(19) United States
(12) Patent Application Publication
(10) Pub. No.: US 2025/0210444 A1
(43) Pub. Date: Jun. 26, 2025

(54) MONITORING OF ELECTRONIC PACKAGES

(71) Applicant: SK Hynix NAND Product Solutions Corp. (dba Solidigm), Rancho Cordova, CA (US)

(72) Inventors: Jorge MARTINEZ ARAIZA, Beaverton, OR (US); Hardeep SINGH, Vancouver (CA)

(21) Appl. No.: 18/393,107

(22) Filed: Dec. 21, 2023

(51) Int. Cl. H01L 23/367; H01L 23/00; H01L 23/373; H01L 23/498; H01L 25/065

(52) U.S. Cl. CPC H01L 23/3672; H01L 23/3735; H01L 23/49816; H01L 24/08; H01L 24/48; H01L 25/0652; H01L 2224/08145; H01L 2224/08155; H01L 2224/4813; H01L 2224/48145; H01L 2924/1205; H01L 2924/1207; H01L 2924/1427; H01L 2924/1438; H01L 2924/15311; H01L 2924/182

(57) ABSTRACT

This application is directed to monitoring a package of an electronic device (e.g., a memory device including a solid state drive (SSD)). The electronic device includes a package substrate, a package, and an interface circuit. The package substrate includes one or more connectors. The package includes a plurality of electrodes that are exposed on a top surface of the package and electrically coupled to the one or more connectors. The interface circuit is coupled to the one or more connectors of the package substrate, and configured to measure one or more electrical signals via the one or more connectors of the package substrate and determine one or more interface parameters of the top surface of the package based on the one or more electrical signals. The package is physically coupled to the package substrate and configured to enclose and protect an integrated circuit (e.g., including the interface circuit).

### TECHNICAL FIELD

This application relates generally to electronic packages including, but not limited to, methods, systems, devices, and circuits for monitoring a package of an electronic device (e.g., a memory device including a solid state drive).

### BACKGROUND

Integrated circuits are formed on semiconductor substrates and protected from exterior environments, as their semiconductor substrates are covered by or enclosed within packages. Non-conductive or conductive materials are applied to the packages during additional assembling operations of module structures (e.g., heatsinks). These materials, if not applied properly, can cause physical damages to the integrated circuits and semiconductor substrates, and easily compromise electrical characteristics or thermal dissipation performance of resulting electronic device. Current electronic packaging technology mainly relies on visual inspection by human or by machine to determine whether the module structures (e.g., heatsinks) have come into contact with their corresponding package surfaces properly. In some situations, transparent module structures and materials are used to facilitate visual inspections, and however, limit options of structures and materials that can be used to package electronic devices. It would be beneficial to develop an effective and efficient mechanism for inspecting a package of an electronic device without compromising thermal and electrical performance of the electronic device, e.g., in high volume production of SSDs and as the SSDs are applied.

### SUMMARY

Various embodiments of this application are directed to methods, systems, devices, and circuits for monitoring a package of an electronic device (e.g., a memory device including an SSD, a memory system including a plurality of SSDs). Electrically conductive pads (i.e., electrodes) are coupled and exposed on a surface of the package, and configured to come into contact with an electrically conductive or non-conductive interface material. An electrical signal is automatically measured from the electrodes and used to determine characteristics of the interface material (e.g., an associated impedance), thereby deriving an existence, a condition, or a type of the interface material, in a non-invasive manner. The interface material is coupled to or includes one of a metallic heatsink, a graphite heat spreader, a thermal interface material (TIM), air, and immersion liquid. The characteristics of the interface material indicate whether the interface material has been applied (e.g., insufficient or excessive TIM is applied) and/or whether a fault condition has occurred.

In some embodiments, the electronic device includes an SSD having an integrated circuit (IC) package. The SSD is mechanically coupled to a thermal structure (e.g., a heatsink) using a thermal interface material (TIM). While and after the thermal structure is assembled with the SSD, electrodes exposed on a surface of the IC package are electrically monitored, allowing the SSD to automatically determine whether the IC package is properly coupled to the thermal structure with the TIM to provide desirable thermal dissipation characteristics. A fault condition occurs and is automatically detected if the TIM is not applied properly, if the TIM ages to cause a change to an electronic device, or if the IC package loses contact to a heatsink. In accordance with a determination that the fault condition occurs, the SSD reports a message including fault information (e.g., a fault type, a fault location). In some embodiments, the IC package is monitored automatically without human intervention (e.g., visual inspection, removing the thermal structure). Particularly, in some situations, the IC package must be isolated from any conductive surfaces, and the SSD does not need to be dissembled to visually inspect whether any air gap is formed between the IC package and a chassis. By these means, the SSD can be effectively and efficiently inspected in a non-invasive manner to avoid shorting or assembly issues in high volume production of SSDs.

In one aspect, a method is implemented to monitor a package of an electronic device. The method includes providing an electronic module including a package and a package substrate. The package includes a plurality of electrodes that are exposed on a top surface of the package and electrically coupled to one or more connectors of the package substrate. The method further includes measuring one or more electrical signals via the one or more connectors of the package substrate and determining one or more interface parameters of the top surface of the package based on the one or more electrical signals.

Some implementations of this application include one of an electronic system (e.g., a memory system), an electronic device (e.g., a memory device), or an electronic module (e.g., a memory module) that includes a package substrate, a package, and an interface circuit and is provided to implement the above methods of monitoring the package of the electronic system, electronic device, or an electronic module. The package substrate includes one or more connectors. The package includes a plurality of electrodes. The plurality of electrodes are exposed on a top surface of the package and electrically coupled to the one or more connectors. The interface circuit is coupled to the one or more connectors of the package substrate, and configured to measure one or more electrical signals via one or more connectors of the package substrate and determine one or more interface parameters of the top surface of the package based on the one or more electrical signals.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a block diagram of an example system module in a typical electronic system in accordance with some embodiments.

FIG. 2 is a block diagram of a memory system of an example electronic system having one or more memory access queues, in accordance with some embodiments.

FIG. 3 is a cross-sectional view of an example electronic module that is electrically monitored via one or more integrated electrodes, in accordance with some embodiments.

FIG. 4 is a top view of an example package having a plurality of electrodes 310 exposed on a top surface of the package, in accordance with some embodiments.

FIGS. 5A and 5B are schematic diagrams of two example interface circuits applied to measure a voltage and a current across two electrodes, in accordance with some embodiments, respectively.

FIG. 6A is a top view of another example package 304 having a plurality of electrodes 310 exposed on a top surface of the package, in accordance with some embodiments, and FIG. 6B is a schematic diagram of an example Wheatstone Bridge diamond shaped circuit coupled to four electrodes shown in FIG. 6A, in accordance with some embodiments.

FIG. 7 is a cross-sectional view of an example electronic device that is electrically monitored via one or more integrated electrodes, in accordance with some embodiments.

FIG. 8 a flow diagram of an example method for monitoring a package of an electronic module, in accordance with some embodiments.

Like reference numerals refer to corresponding parts throughout the several views of the drawings.

### DETAILED DESCRIPTION

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic systems or devices with data storage capabilities.

This application is directed to monitoring a package of an electronic device (e.g., a memory device including a solid state drive). Electrically conductive pads (i.e., electrodes) are coupled and exposed on a surface of the package, and configured to come into contact with an electrically conductive or non-conductive interface material. An electrical signal is automatically measured from the electrodes and used to determine characteristics of the interface material (e.g., an associated impedance), thereby deriving an existence, a condition, or a type of the interface material, in a non-invasive manner. The interface material is coupled to or includes one of a metallic heatsink, a graphite heat spreader, a thermal interface material (TIM), air, and immersion liquid. The characteristics of the interface material indicate whether proper application of the interface material or a fault condition has occurred (e.g., insufficient or excessive TIM is applied). In some embodiments, the electronic device includes an SSD having an integrated circuit (IC) package. The electrical signal is applied to monitor a condition regarding the SSD of the electronic device. By these means, the SSD can be effectively and efficiently inspected in a non-invasive manner to avoid shorting or assembly issues in high volume production.

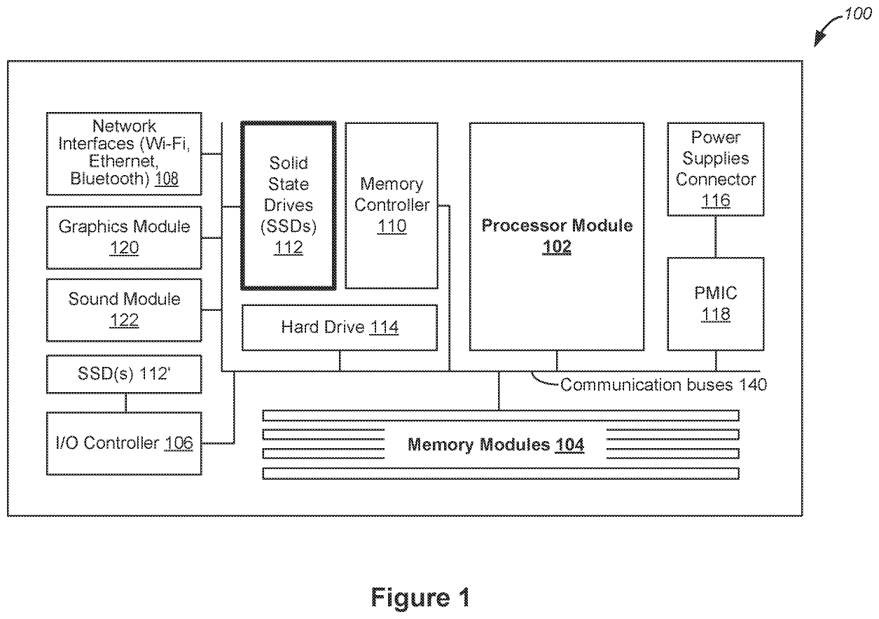

FIG. 1 is a block diagram of an example system module 100 in a typical electronic system in accordance with some embodiments. The system module 100 in this electronic system includes at least a processor module 102, memory modules 104 for storing programs, instructions and data, an input/output (I/O) controller 106, one or more communication interfaces such as network interfaces 108, and one or more communication buses 140 for interconnecting these components. In some embodiments, the I/O controller 106 allows the processor module 102 to communicate with an I/O device (e.g., a keyboard, a mouse or a trackpad) via a universal serial bus interface. In some embodiments, the network interfaces 108 includes one or more interfaces for Wi-Fi, Ethernet and Bluetooth networks, each allowing the electronic system to exchange data with an external source, e.g., a server or another electronic system. In some embodiments, the communication buses 140 include circuitry (sometimes called a chipset) that interconnects and controls communications among various system components included in system module 100.

In some embodiments, the memory modules 104 include high-speed random-access memory, such as static random-access memory (SRAM), double data rate (DDR) dynamic random-access memory (DRAM), or other random-access solid state memory devices. In some embodiments, the memory modules 104 include non-volatile memory, such as one or more magnetic disk storage devices, optical disk storage devices, flash memory devices, or other non-volatile solid state storage devices. In some embodiments, the memory modules 104, or alternatively the non-volatile memory device(s) within the memory modules 104, include a non-transitory computer readable storage medium. In some embodiments, memory slots are reserved on the system module 100 for receiving the memory modules 104. Once inserted into the memory slots, the memory modules 104 are integrated into the system module 100.

In some embodiments, the system module 100 further includes one or more components selected from a memory controller 110, SSD(s) 112, an HDD 114, power management integrated circuit (PMIC) 118, a graphics module 120, and a sound module 122. The memory controller 110 is configured to control communication between the processor module 102 and memory components, including the memory modules 104, in the electronic system. The SSD(s) 112 are configured to apply integrated circuit assemblies to store data in the electronic system, and in many embodiments, are based on NAND or NOR memory configurations. The HDD 114 is a conventional data storage device used for storing and retrieving digital information based on electromechanical magnetic disks. The power supply connector 116 is electrically coupled to receive an external power supply. The PMIC 118 is configured to modulate the received external power supply to other desired DC voltage levels, e.g., 5V, 3.3V or 1.8V, as required by various components or circuits (e.g., the processor module 102) within the electronic system. The graphics module 120 is configured to generate a feed of output images to one or more display devices according to their desirable image/video formats. The sound module 122 is configured to facilitate the input and output of audio signals to and from the electronic system under control of computer programs.

Alternatively or additionally, in some embodiments, the system module 100 further includes SSD(s) 112′ coupled to the I/O controller 106 directly. Conversely, the SSDs 112 are coupled to the communication buses 140. In an example, the communication buses 140 operates in compliance with Peripheral Component Interconnect Express (PCIe or PCI-E), which is a serial expansion bus standard for interconnecting the processor module 102 to, and controlling, one or more peripheral devices and various system components including components 110-122.

Further, one skilled in the art knows that other non-transitory computer readable storage media can be used, as new data storage technologies are developed for storing information in the non-transitory computer readable storage media in the memory modules 104, SSD(s) 112 or 112′, and HDD 114. These new non-transitory computer readable storage media include, but are not limited to, those manufactured from biological materials, nanowires, carbon nanotubes and individual molecules, even though the respective data storage technologies are currently under development and yet to be commercialized.

Various embodiments of this application are directed to methods, systems, devices, and circuits for monitoring a package of an electronic device. Electrically conductive pads (i.e., electrodes) are coupled and exposed on a surface of the package, and configured to come into contact with an electrically conductive or non-conductive material. An electrical signal is automatically measured from the electrodes and used to determine characteristics of the material (e.g., an associated impedance), thereby deriving an existence, a condition, or a type of the material, in a non-invasive manner. The material is coupled to or includes one of a metallic heatsink, a graphite heat spreader, a thermal interface material (TIM), air, and immersion liquid. In some embodiments, the electronic device includes any of the electronic components 102-122.

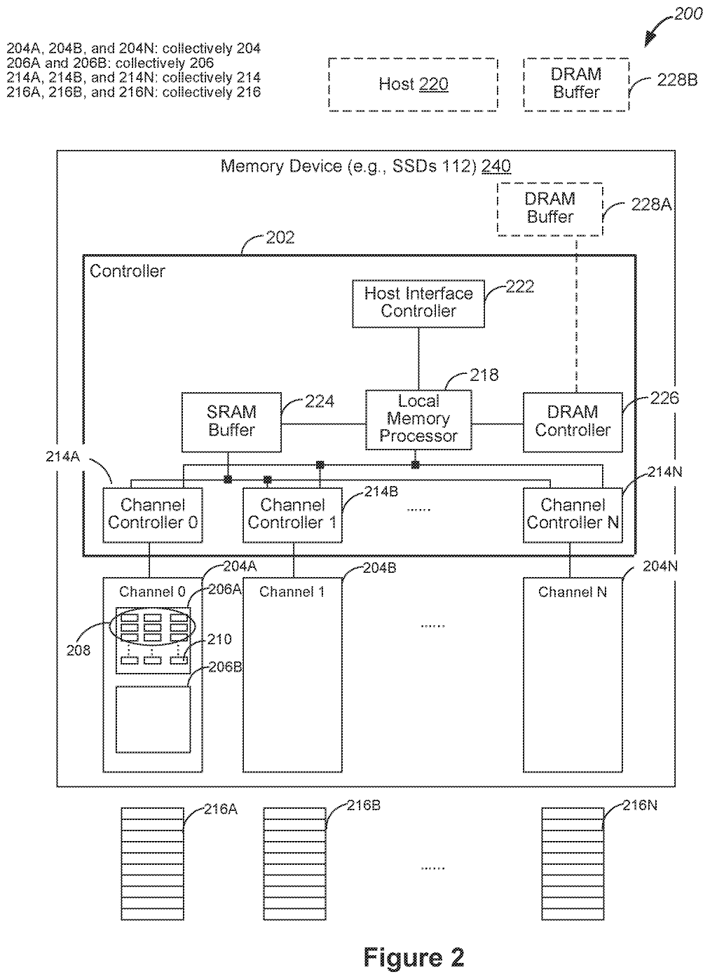

FIG. 2 is a block diagram of a memory system 200 of an example electronic device having one or more memory access queues, in accordance with some embodiments. The memory system 200 is coupled to a host device 220 (e.g., a processor module 102 in FIG. 1) and configured to store instructions and data for an extended time, e.g., when the electronic device sleeps, hibernates, or is shut down. The host device 220 is configured to access the instructions and data stored in the memory system 200 and process the instructions and data to run an operating system and execute user applications. The memory system 200 includes one or more memory devices 240 (e.g., SSD(s)). Each memory device 240 further includes a controller 202 and a plurality of memory channels 204 (e.g., channel 204A, 204B, and 204N). Each memory channel 204 includes a plurality of memory cells. The controller 202 is configured to execute firmware level software to bridge the plurality of memory channels 204 to the host device 220. In some embodiments, each memory device 240 is formed on a printed circuit board (PCB).

Each memory channel 204 includes on one or more memory packages 206 (e.g., two memory dies). In an example, each memory package 206 (e.g., memory package 206A or 206B) corresponds to a memory die. Each memory package 206 includes a plurality of memory planes 208, and each memory plane 208 further includes a plurality of memory pages 210. Each memory page 210 includes an ordered set of memory cells, and each memory cell is identified by a respective physical address. In some embodiments, the memory device 240 includes a plurality of superblocks. Each superblock includes a plurality of memory blocks each of which further includes a plurality of memory pages 210. For each superblock, the plurality of memory blocks are configured to be written into and read from the memory system via a memory input/output (I/O) interface concurrently. Optionally, each superblock groups memory cells that are distributed on a plurality of memory planes 208, a plurality of memory channels 204, and a plurality of memory dies 206. In an example, each superblock includes at least one set of memory pages, where each page is distributed on a distinct one of the plurality of memory dies 206, has the same die, plane, block, and page designations, and is accessed via a distinct channel of the distinct memory die 206. In another example, each superblock includes at least one set of memory blocks, where each memory block is distributed on a distinct one of the plurality of memory dies 206 includes a plurality of pages, has the same die, plane, and block designations, and is accessed via a distinct channel of the distinct memory die 206. The memory device 240 stores information of an ordered list of superblocks in a cache of the memory device 240. In some embodiments, the cache is managed by a host driver of the host device 220, and called a host managed cache (HMC).

In some embodiments, the memory device 240 includes a single-level cell (SLC) NAND flash memory chip, and each memory cell stores a single data bit. In some embodiments, the memory device 240 includes a multi-level cell (MLC) NAND flash memory chip, and each memory cell of the MLC NAND flash memory chip stores 2 data bits. In an example, each memory cell of a triple-level cell (TLC) NAND flash memory chip stores 3 data bits. In another example, each memory cell of a quad-level cell (QLC) NAND flash memory chip stores 4 data bits. In yet another example, each memory cell of a penta-level cell (PLC) NAND flash memory chip stores 5 data bits. In some embodiments, each memory cell can store any suitable number of data bits. Compared with the non-SLC NAND flash memory chips (e.g., MLC SSD, TLC SSD, QLC SSD, PLC SSD), the SSD that has SLC NAND flash memory chips operates with a higher speed, a higher reliability, and a longer lifespan, and however, has a lower device density and a higher price.

Each memory channel 204 is coupled to a respective channel controller 214 (e.g., controller 214A, 214B, or 214N) configured to control internal and external requests to access memory cells in the respective memory channel 204. In some embodiments, each memory package 206 (e.g., each memory die) corresponds to a respective queue 216 (e.g., queue 216A, 216B, or 216N) of memory access requests. In some embodiments, each memory channel 204 corresponds to a respective queue 216 of memory access requests. Further, in some embodiments, each memory channel 204 corresponds to a distinct and different queue 216 of memory access requests. In some embodiments, a subset (less than all) of the plurality of memory channels 204 corresponds to a distinct queue 216 of memory access requests. In some embodiments, all of the plurality of memory channels 204 of the memory device 240 corresponds to a single queue 216 of memory access requests. Each memory access request is optionally received internally from the memory device 240 to manage the respective memory channel 204 or externally from the host device 220 to write or read data stored in the respective channel 204. Specifically, each memory access request includes one of: a system write request that is received from the memory device 240 to write to the respective memory channel 204, a system read request that is received from the memory device 240 to read from the respective memory channel 204, a host write request that originates from the host device 220 to write to the respective memory channel 204, and a host read request that is received from the host device 220 to read from the respective memory channel 204. It is noted that system read requests (also called background read requests or non-host read requests) and system write requests are dispatched by a memory controller to implement internal memory management functions including, but are not limited to, garbage collection, wear levelling, read disturb mitigation, memory snapshot capturing, memory mirroring, caching, and memory sparing.

In some embodiments, in addition to the channel controllers 214, the controller 202 further includes a local memory processor 218, a host interface controller 222, an SRAM buffer 224, and a DRAM controller 226. The local memory processor 218 accesses the plurality of memory channels 204 based on the one or more queues 216 of memory access requests. In some embodiments, the local memory processor 218 writes into and read from the plurality of memory channels 204 on a memory block basis. Data of one or more memory blocks are written into, or read from, the plurality of channels jointly. No data in the same memory block is written concurrently via more than one operation. Each memory block optionally corresponds to one or more memory pages. In an example, each memory block to be written or read jointly in the plurality of memory channels 204 has a size of 16 KB (e.g., one memory page). In another example, each memory block to be written or read jointly in the plurality of memory channels 204 has a size of 64 KB (e.g., four memory pages). In some embodiments, each page has 16 KB user data and 2 KB metadata. Additionally, a number of memory blocks to be accessed jointly and a size of each memory block are configurable for each of the system read, host read, system write, and host write operations.

In some embodiments, the local memory processor 218 stores data to be written into, or read from, each memory block in the plurality of memory channels 204 in an SRAM buffer 224 of the controller 202. Alternatively, in some embodiments, the local memory processor 218 stores data to be written into, or read from, each memory block in the plurality of memory channels 204 in a DRAM buffer 228A that is included in memory device 240, e.g., by way of the DRAM controller 226. Alternatively, in some embodiments, the local memory processor 218 stores data to be written into, or read from, each memory block in the plurality of memory channels 204 in a DRAM buffer 228B that is main memory used by the processor module 102 (FIG. 1). The local memory processor 218 of the controller 202 accesses the DRAM buffer 228B via the host interface controller 222.

Various embodiments of this application are directed to methods, systems, devices, and circuits for monitoring a package of an electronic device (e.g., a memory device including an SSD, a memory system including a plurality of SSDs). Electrically conductive pads (i.e., electrodes) are coupled and exposed on a surface of the package, and configured to come into contact with an electrically conductive or non-conductive material. An electrical signal is automatically measured from the electrodes and used to determine characteristics of the material (e.g., an associated impedance), thereby deriving an existence, a condition, or a type of the material, in a non-invasive manner. The material is coupled to or includes one of a metallic heatsink, a graphite heat spreader, a thermal interface material (TIM), air, and immersion liquid. In some embodiments, the electronic device includes an SSD having an integrated circuit (IC) package. For example, a fault condition occurs to the SSD and is automatically detected if the TIM is not applied properly, if the TIM ages to cause a change to an electronic device, or if the IC package loses contact to a heatsink. In accordance with a determination that the fault condition occurs, the SSD reports a message including fault information (e.g., a fault type, a fault location). The IC package is monitored automatically without human intervention (e.g., visual inspection, removing the thermal structure) and without being isolated from the TIM or dissembled. By these means, the SSD can be effectively and efficiently inspected in a non-invasive manner to avoid shorting or assembly issues in high volume production.

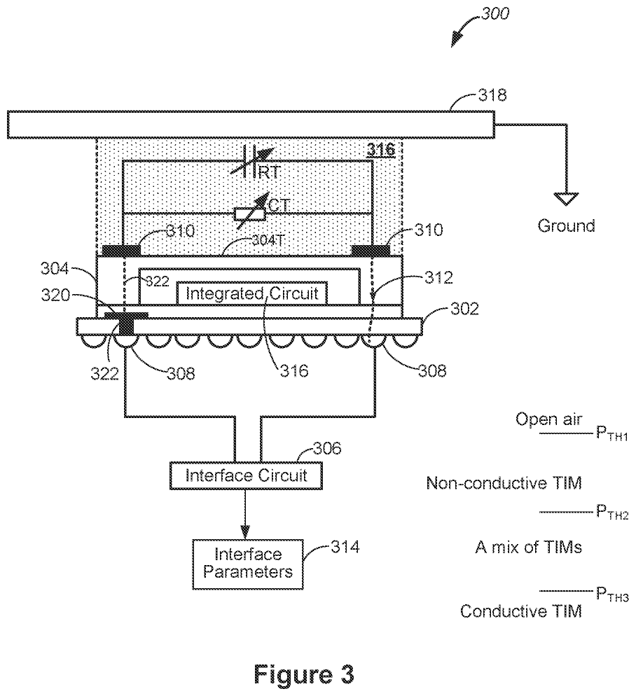

FIG. 3 is a cross-sectional view of an example electronic module 300 that is electrically monitored via one or more integrated electrodes, in accordance with some embodiments. The electronic module 300 includes a package substrate 302, a package 304, and an interface circuit 306. The package 302 includes one or more connectors 308, and the package 304 includes a plurality of electrodes 310. The plurality of electrodes 310 are exposed on a top surface 304T of the package 304, and electrically coupled to the one or more connectors 308. The interface circuit 306 is coupled to the one or more connectors 308 of the package substrate 302, and is configured to measure one or more electrical signals 312 via one or more connectors 308 of the package substrate 302 and determine one or more interface parameters 314 of the top surface of the package based on the one or more electrical signals. In some embodiments, the interface circuit 306 further measures one or more of: a voltage level, a current level, a rise time, a fall time, a delay time, a duty cycle, a high level time, and a low level time of a subset of the one or more electrical signals 312.

In some embodiments, the package 304 is physically coupled to the package substrate 302 and configured to enclose and protect one or more integrated circuit chips 315. The electronic module 300 further includes the one or more integrated circuit chips 315, and the one or more integrated circuit chips 315 further include the interface circuit 306. The interface circuit 306 is electrically coupled to the one or more connectors 308 of the package substrate 302 via one or more conductor traces of the package substrate 302, and configured to measure the one or more electrical signals 312 and determine the one or more interface parameters 314.

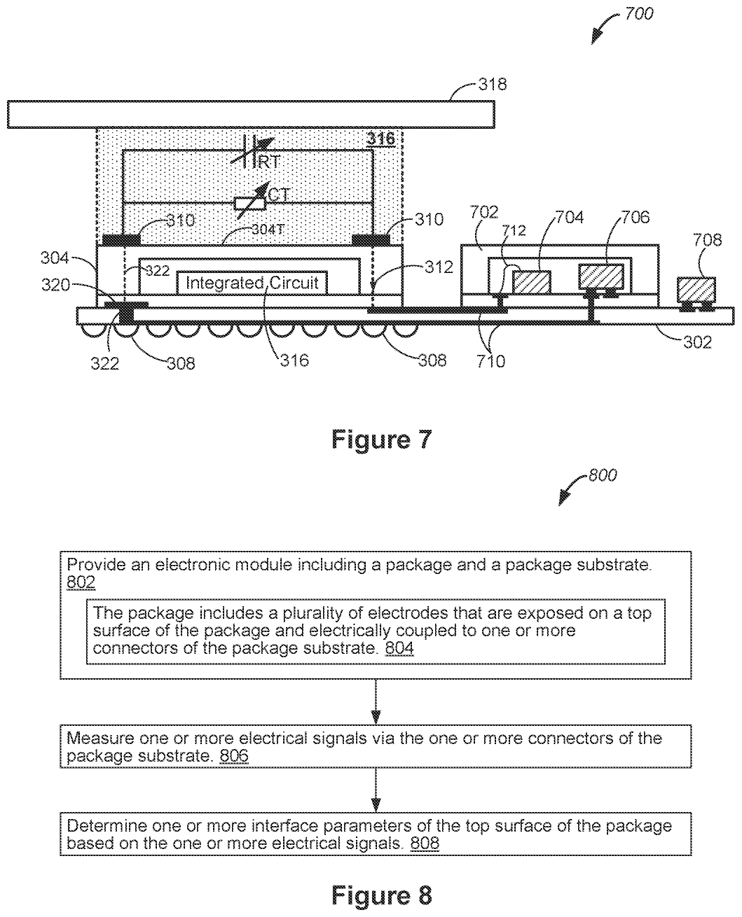

In some embodiments, each of a subset of electrodes 310 is coupled to an electrical path 322 that runs through the package 304 and is coupled to an electrically conductive pad 320 on a bottom surface of the package 304, and the electrically conductive pad 320 on the bottom surface of the package 304 is electrically coupled to a respective one of the one or more connectors 308. Each of the one or more connectors 308 is optionally located on a top surface or a bottom surface of the substrate 302. In an example, a connector 308 includes a solder ball disposed on a surface of the substrate 302. In another example, the connector 308 does not include a solder ball, and broadly includes a conductive pad 320 or a trace (e.g., 710 in FIG. 7) formed on or in the package substrate 302.

In some embodiments not shown, the package substrate 302 includes a main printed circuit board (PCB). The interface circuit 306 is mounted on the main printed circuit board and electrically coupled to the one or more connectors 308 of the package substrate 302 via one or more conductor traces of the main PCB. In some embodiments, the electronic module 300 further includes an SSD, and a plurality of memory chips 206 of the SSD are enclosed in the package 304, which is further mounted on the package substrate 302, and the electronic module 300 is applied in a data center computer system. Further, in some embodiments, a plurality of packages 304 are mounted on the same main PCB of the package substrate 302, and a first one of the package 304 includes a memory controller 202. Each of a subset of the packages 304 includes one or more respective memory chips 206.

In some embodiments, the one or more interface parameters 314 include an impedance that is associated with the plurality of electrodes 310 exposed on the top surface of the package 304. In accordance with a determination that the impedance is greater than a first impedance threshold P_{TH1}, the interface circuit 306 determines that the top surface 304T of the package 304 is next to an air gap. In accordance with a determination that the impedance is greater than a second impedance threshold P_{TH2}, the interface circuit 306 determines that the top surface 304T of the package 304 is next to a non-conductive thermal interface material (TIM) 316. In accordance with a determination that the impedance is less than a third impedance threshold P_{TH3}, the interface circuit 306 determines that the top surface 304T of the package 304 is next to an electrically conductive TIM 318. Referring to FIG. 3, in accordance with a determination that the impedance is between the second and third impedance thresholds P_{TH2} and P_{TH3}, the interface circuit 306 determines that the top surface 304T of the package 304 is next to the non-conductive TIM 316 and further to an electrically conductive TIM 318. The first impedance threshold P_{TH1} is greater than the second impedance threshold P_{TH2}, which is greater than the third impedance threshold P_{TH3}. Further, in some embodiments, the impedance thresholds P_{TH1}, P_{TH2}, and P_{TH3} are determined based on a type of the conductive TIM 318 and a type of the non-conductive TIM 316.

In some embodiments, the one or more interface parameters 314 include a change of the impedance associated with the plurality of electrodes 310. In accordance with a determination that the change of the impedance (e.g., corresponding to a magnitude) is greater than a change threshold DP_{TH}, the interface circuit 306 determines that a change of a surface condition has occurred to the top surface 304T of the package 304. For example, in some situations, the top surface 304T of the package 304 is coupled to an electrically conductive TIM 318 (e.g., a heatsink) via a layer of non-conductive TIM 316, and the electrically conductive TIM 318 is detached from the package 304, thereby causing the impedance to increase by the change greater than a first change threshold DP_{TH1}. In some situations, the top surface 304T of the package 304 is coupled to an electrically conductive TIM 318 (e.g., a heatsink) directly, and the electrically conductive TIM 318 is detached from the package 304 to make the top surface 304T of the package 304 exposed to open air. The change of the impedance exceeds a second change threshold DP_{TH1}. As such, the interface circuit 306 compares the change of the impedance with one or more change thresholds to determine that a type of a surface condition change has occurred to the top surface 304T of the package 304.

In some embodiments, a heat controlling module (e.g., the TIM 318) is disposed in proximity to, and separated by a gap from, the top surface 304T of the package 304. The interface circuit 306 determines gap characteristics of the gap, e.g., based on the one or more interface parameters 314 of the top surface 304T of the package 304. Further, in some embodiments, the one or more electrical signals 312 are measured and the one or more interface parameters 314 are determined during an extended duration of time. The interface circuit 306 monitors a variation of the gap characteristics of the gap during the extended duration of time. Specifically, in some embodiments, the interface circuit 306 determines one or more of: a type, a material state, a material quality, a temperature, a coverage, a uniformity level, a damage condition, and a variation of a gap material that fills the gap, e.g., based on the one or more interface parameters 314 of the top surface 304T of the package 304. In some implementations, the gap between the package and the heat controlling module is filled with air, a TIM 316, or a combination thereof, and the TIM 316 includes one or more of: a thermal paste, a thermal adhesive, a thermal gap filler, a thermally conductive pad, a phase-change material, a thermal tape, and a metal thermal interface material. Additionally, under some circumstances, based on the one or more interface parameters 314, it is determined that the gap material (e.g., the TIM 316) loses contact to the heat controlling module (e.g., the TIM 318). In some embodiments, the heat controlling module (e.g., the electrically conductive TIM 318) is electrically coupled to ground.

In some embodiments, the interface circuit 306 determines that the one or more interface parameters 314 do not satisfy a package criterion, and generates an alert message to report an associated package failure condition. For example, the package criterion requires that the TIM 318 to be attached to the package 304 via the TIM 316 for dissipating heat effectively and efficiently. In accordance with a determination that an associated impedance exceeds the second impedance threshold P_{TH2}, the interface circuit 306 detects detachment of at least the TIM 318, and the alert message is generated to report the package failure condition. In some embodiments, the interface circuit 306 is configured to configured to monitor the package failure condition in real time during normal operation of the electronic device 300 (e.g., while an SSD is accessed to write and read data stored therein). In response to the alert message, the electronic device immediately disables a power-intensive mode, powers off its operations entirely, or enters a trouble-shooting mode, before the electronic device is damaged under the package failure condition.

In some embodiments, a plurality of electrodes 310 (i.e., electrically conductive pads) are formed on a top surface 304T of a package 304, and configured to enable measurement of an impedance between two electrodes 310 and detection of a type of a material that is applied to that top surface 304T. In some embodiments, the package 304 is left without any material (e.g., no TIM 316, no heatsink 318). The impedance between the electrodes 310 is greater than an impedance limit or the first impedance threshold P_{TH1} (e.g., has an impedance near infinity) and corresponds to open air. Alternatively, in some embodiments, a non-conductive material 316 (e.g., TIM) is applied on the top surface 304T of the package 304. The impedance between the electrodes 310 is lower than the impedance limit or first impedance threshold P_{TH1} and greater than the second impedance threshold P_{TH2}, thereby indicating a high impedance environment. Alternatively, in some embodiments, a conductive material 318 (such as a metallic heatsink) is directly applied on the top surface 304T of the package 304 through direct contact or thin-film conductive epoxy. The impedance between the electrodes 310 is lower than the second impedance threshold P_{TH2}, thereby indicating a low impedance environment. Alternatively and additionally, in some embodiments, a non-conductive material (e.g., an TIM 316) is applied, and a grounded conductive material 318 (e.g., a metallic heatsink) contacts the non-conductive material 316. The impedance between the electrodes 310 changes in response to the grounded conductive material is detached and the non-conductive material is exposed to open air directly. In an example, a change of the impedance indicates a loss of contact between the TIM 316 and the heatsink 318 has occurred. If no change is detected or the change is substantially small (e.g., below a respective change threshold), the TIM 316 stays in contact with the heatsink 318 and is not detached from the heatsink 318. Alternatively, in some embodiments, an air gap separates a top surface 304T of the package 304 from an enclosure or chassis (e.g., the TIM 318), and the impedance between the electrodes 310 corresponds to a respective impedance range.

The package 304 has a plurality of electrically conductive pads 310 (also called pins, electrodes 310) that are exposed on a top surface 304T of the package 304. Each of a subset of electrodes 310 has an electrical connection to a package substrate 302 via wire-bond conductive pillars, such that an interface circuit 306 is electrically coupled to the wire-bond conductive pillars to drive the subset of electrodes 310, sense electrical signals provided by, and/or determine the impedance among the subset of electrodes 310.

In some embodiments, a current source provides an electrical signal to be applied on one more active electrodes 310, while one or more passive electrodes 310 are coupled to ground. The interface circuit 306 is configured to measure a voltage that drops across, or a current that flows between, the active electrodes 310 and the passive electrodes 310. The interface circuit 306 is also configured to estimate an impedance of the material coupled between the active and passive electrodes 310, which is optionally resistive, capacitive, or a combination thereof. Based on different materials, the interface circuit 306 detects any scenarios that correlate to materials placed on the top surface 304T of the package 304. In some embodiments, no material is coupled to the electrodes 310, and the electrodes 310 are exposed to air. The interface circuit 306 measures a near-infinite impedance (e.g., greater than a threshold P_{TH1}) which correlates with an open circuit scenario, indicating the electrodes 310 are exposed to open air. In some embodiments, a highly conductive material 318 is coupled to the electrodes 310 (e.g., a metal heatsink, a graphite heat spreader), and the interface circuit 306 senses a near-zero impedance (e.g., less than a threshold P_{TH3}), which is correlated with a short circuit between the electrodes 310, and indicates that a highly conductive material is coupled between the electrodes 310. In some embodiments, a non-conductive material (e.g. TIM) is placed on the top surface 304T of the package 304 without being further coupled to any other conductive materials (e.g., a metallic heat ink), the interface circuit 306 detects a current flow between the electrodes 310, which indicates TIM has been applied. A magnitude of the current flow depends on the impedance of the material, and is used to differentiate different types of materials that have different electrical volume resistivity characteristics and/or material thickness. In some embodiments, the non-conductive (e.g., TIM) material 316 is applied and a conductive material 318 is also applied (e.g., grounded heatsink). The impedance measured by the interface circuit 306 is less than that of another impedance corresponding to a non-conductive TIM only scenario. A current flowing through the material has a shorter path to go through between the active and grounded electrodes 310, thereby enabling the interface circuit 306 to detect that a proper contact is formed between the non-conductive material 316 and the conductive material 318 (e.g., between the TIM and the heatsink).

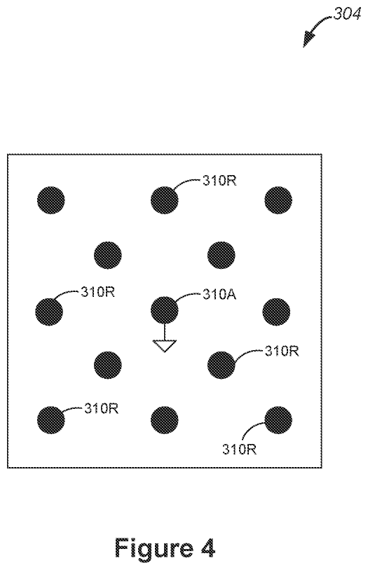

FIG. 4 is a top view of an example package 304 having a plurality of electrodes 310 exposed on a top surface 304T of the package 304, in accordance with some embodiments. As explained above, an electronic device 300 includes a package substrate 302 having one or more connectors 308, a package 304 having a plurality of electrodes 310, and an interface circuit 306 coupled to the one or more connectors 308 of the package substrate 302. The plurality of electrodes 310 are exposed on a top surface 304T of the package 304 and electrically coupled to the one or more connectors 308. The interface circuit 306 is configured to measure one or more electrical signals 312 via one or more connectors 308 of the package substrate 302 and determine one or more interface parameters of the top surface 304T of the package 304 based on the one or more electrical signals 312. In some embodiments, the plurality of electrodes 310 is distributed on the top surface 304T of the package 304, and the one or more interface parameters of the top surface 304T of the package 304 include one or more of: an impedance value, a distribution of impedance, an RC time, and a distribution of RC time.

In some embodiments, a first subset of the plurality of electrodes 310 (e.g., a first electrode 310A) is coupled to ground. The one or more interface parameters 314 of the top surface 304T of the package 304 include an impedance of each of a second subset of electrodes (e.g. a remaining electrode 310R distinct from the first electrode 310A) with reference to the ground. For example, in some embodiments, the plurality of electrodes 310 include a first electrode 310A and a set of remaining electrodes 310R each of which is distinct from the first electrode 310A. An electrical signal 312 is measured between each remaining electrode 310R and the first electrode 310A, thereby determining the distribution of impedance or the distribution of RC time. In some embodiments, the plurality of electrodes 310 are distributed evenly on the top surface 304T of the package 304, and the distribution of impedance or the distribution of RC time is measured to determine whether the TIM 316 or 318 has been coupled properly or started a fault condition. Further, in some embodiments, the first electrode 310A is grounded. The first electrode 310A is optionally located in a center, a corner, or a predefined location of the top surface 304T of the package 304.

In some embodiments, every two of the plurality of electrodes 310 are coupled via a resistor RT and a capacitor CT, which depend on a material coupled between the respective two electrodes 310. For example, a conductive TIM 318 coupled directly to the electrodes 310 corresponds to a resistor RT that has a substantially low resistance (e.g., lower than a threshold resistance). In another example, the top surface 304T is exposed to open air without any TIM 316 or 318, and the resistor RT is substantially large (e.g., infinite), and the capacitor CT has a capacitance. In some embodiments, a non-conductive TIM 316 is applied on the top surface 304T, and a conductive TIM 318 is coupled to the electrodes 310 via the non-conductive TIM 316. The capacitor CT and resistor RT are coupled in parallel, and depend on characteristics of the TIMs 316 and 318. The impedance value and the RC time measured between two of the plurality of electrodes 310 are determined by the capacitor CT and resistor RT.

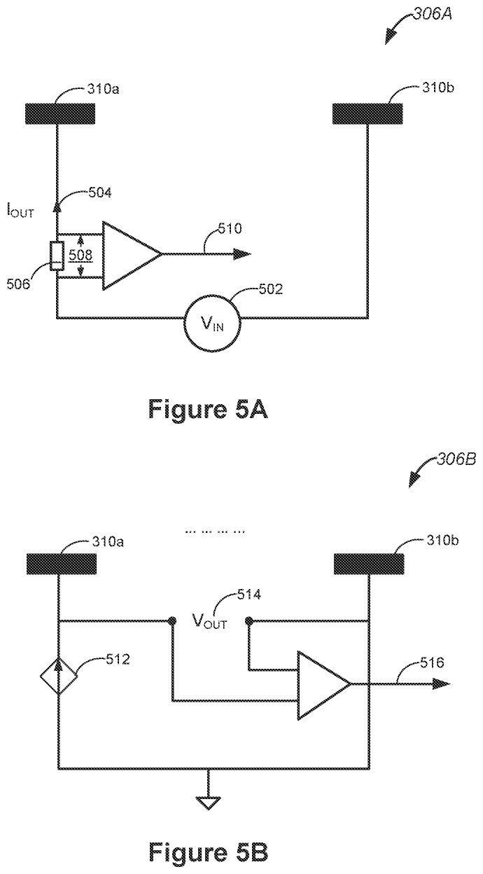

FIGS. 5A and 5B are schematic diagrams of two example interface circuits 306A and 306B applied to measure a voltage and a current across two electrodes 310a and 310b, in accordance with some embodiments, respectively. Referring to FIG. 5A, in some embodiments, a first drive voltage 502 is applied on the electrodes 310a and 310b, and a first drive current 504 passing through the electrodes 310a and 310b is measured. In some embodiments, the first drive voltage 502 is applied on the electrodes 310a and 310b via a sense resistor 506 having a substantial low resistance. A voltage drop 508 across the sense resistor 506 is monitored across the sense resistor 506 to determine the first drive current 504. In some embodiments, the voltage drop 508 is amplified to generate an amplified voltage drop 510. Referring to FIG. 5B, in some embodiments, a second drive current 512 is delivered to the electrodes 310a and returned via the electrode 310b, and a second drive voltage 514 is measured between the electrodes 310a and 310b. In some embodiments, the second drive voltage 514 is amplified to generate an amplified drive voltage 516. As such, the voltage drop 508 or 510 (FIG. 5A) and drive voltage 514 or 516 (FIG. 5B) is monitored and applied to determine one or more interface parameters 314 of the top surface 304T of the package 304.

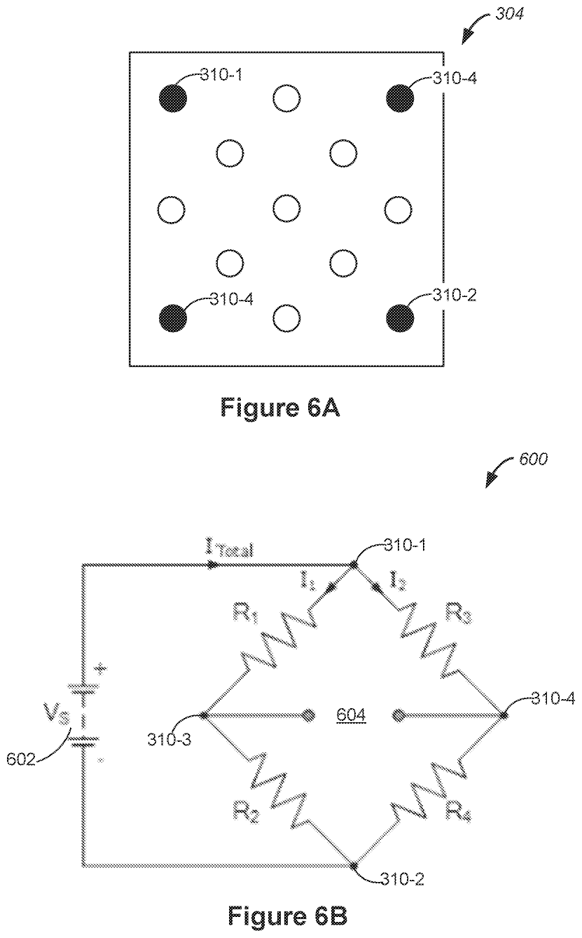

FIG. 6A is a top view of another example package 304 having a plurality of electrodes 310 exposed on a top surface 304T of the package 304, in accordance with some embodiments, and FIG. 6B is a schematic diagram of an example Wheatstone Bridge diamond shaped circuit 600 coupled to four electrodes 310-1 to 310-4 shown in FIG. 6A, in accordance with some embodiments. The plurality of electrodes 310 include four electrodes 310 (e.g., 310-1 to 310-4) that are distributed at four substantially symmetric locations on the top surface 304T of the package 304 (e.g., at four corners of the top surface 304T), and the four electrodes 310 are coupled to form four nodes of a Wheatstone Bridge diamond shaped circuit 600. Equivalent resistors R1, R2, R3, and R4 are formed between the electrodes 310-1 and 310-3, between the electrodes 310-3 and 310-2, between the electrodes 310-1 and 310-4, and between the electrodes 310-4 and 310-2, respectively.

A drive voltage 602 is applied to drive the circuit 600 (e.g., on the electrodes 310-1 and 310-2), and a balance voltage 604 is checked on two arms of the circuit 600 (e.g., on the electrodes 310-3 and 310-4). In some embodiments, based on the balance voltage 604, the interface circuit 306 determines that a portion of a gap that is formed above the top surface 304T of the package 304 has varied, e.g., because the balance voltage 604 is not substantially low any more.

FIG. 7 is a cross-sectional view of an example electronic device 700 that is electrically monitored via one or more integrated electrodes 310, in accordance with some embodiments. In some embodiments, the package substrate 302 includes a main printed circuit board (PCB). In some embodiments, a second package 702 is mounted on a top surface (FIG. 7) or a bottom surface of the package 302, and encloses one or more integrated circuit chips 704 and 706. The one or more integrated circuit chips 704 and 706 include the interface circuit 306. Each integrated circuit chip 704 or 706 is electrically coupled to the one or more connectors 308 of the package substrate 302 via one or more conductor traces 710 of the main PCB. In some embodiments, the integrated circuit chip 706 is flip-chip mounted on the main PCB and electrically coupled to the one or more connectors 308 via the one or more conductor traces 710. The integrated circuit chip 704 optionally includes the interface circuit 306. Alternatively, in some embodiments, the integrated circuit chip 704 faces up, and is electrically coupled to electrical pads formed on the top surface of the package substrate 302 using bonding wires 712 and further to the one or more connectors 308 via the one or more conductor traces 710.

In some embodiments, an integrated circuit chip 708 is directly mounted on the main PCB and includes the interface circuit 306. The interface circuit 306 is electrically coupled to the one or more connectors 308 of the package substrate 302 via one or more conductor traces of the main PCB. In some embodiments, the interface circuit 306 is flip-chip mounted on the main PCB. Alternatively, in some embodiments, the interface circuit 306 faces up and is electrically coupled to electrical pads formed on the top surface of the package substrate 302 using bonding wires.

In some embodiments, the electronic module 300 further includes an SSD, and a plurality of memory chips 206 of the SSD are enclosed in the package 304, which is further mounted on the package substrate 302, and the electronic module 300 is applied in a data center computer system. Further, in some embodiments, a plurality of packages 304 are mounted on the same main PCB of the package substrate 302, and a first one of the package 304 (e.g., 702) includes a memory controller 202. Each of a subset of the packages 304 includes one or more respective memory chips 206. Additionally, in some embodiments, the memory controller 202 in the first one of the package 304 includes the interface circuit 306 configured to measure the one or more electrical signals 312 collected from the first one of the package 304, the subset of the packages 304 containing the memory chips 206, or both.

FIG. 8 is a flow diagram of an example method 800 for monitoring a package 304 of an electronic module 300, in accordance with some embodiments. An electronic module 300 (FIG. 3) is (operation 802) provided and includes a package 304 and a package substrate 302. The package 304 includes (operation 804) a plurality of electrodes 310 that are exposed on a top surface 304T of the package 304 and electrically coupled to one or more connectors 308 of the package substrate 302. One or more electrical signals 312 are measured (operation 806) via the one or more connectors 308 of the package substrate 302. One or more interface parameters 314 of the top surface 304T of the package 304 are determined (operation 808) based on the one or more electrical signals 312.

In some embodiments, the package 304 is physically coupled to the package substrate 302 and configured to enclose and protect an integrated circuit 315 (FIG. 3).

In some embodiments, the electronic module further includes the integrated circuit 315, and the integrated circuit 315 further includes an interface circuit 306. The interface circuit 306 is electrically coupled to the one or more connectors 308 of the package substrate 302 via one or more conductor traces of the package substrate 302, and configured to measure the one or more electrical signals 312 and determine the one or more interface parameters 314.

In some embodiments, the package substrate 302 includes a main printed circuit board (FIG. 7). An interface circuit 306 is configured to measure the one or more electrical signals 312 and determine the one or more interface parameters 314. The interface circuit 306 is mounted on the main printed circuit board and electrically coupled to the one or more connectors 308 of the package substrate 302 via one or more conductor traces 710 (FIG. 7) of the main printed circuit board.

In some embodiments, the one or more electrical signals 312 further include one or more of: a voltage level, a current level, a rise time, a fall time, a delay time, a duty cycle, a high level time, and a low level time of a subset of the one or more electrical signals 312.

In some embodiments, the one or more interface parameters 314 include an impedance that is associated with the plurality of electrodes 310 exposed on the top surface 304T of the package 304. In accordance with a determination that the impedance is greater than a first impedance threshold P_{TH1} (FIG. 3), it is determined that the top surface 304T of the package 304 is next to an air gap. In accordance with a determination that the impedance is greater than a second impedance threshold P_{TH2}, it is determined that the top surface 304T of the package 304 is next to a non-conductive thermal interface material 316. In accordance with a determination that the impedance is less than a third impedance threshold P_{TH3}, it is determined that the top surface 304T of the package 304 is next to an electrically conductive thermal interface material 318. In accordance with a determination that the impedance is between the second and third impedance thresholds (P_{TH2} and P_{TH3}), it is determined that the top surface 304T of the package 304 is next to the non-conductive thermal interface material 316 and further to an electrically conductive thermal interface material 318. The first impedance threshold P_{TH1} is greater than the second impedance threshold P_{TH2}, which is greater than the third impedance threshold P_{TH3}.

In some embodiments, the plurality of electrodes 310 is distributed on the top surface 304T of the package 304, and the one or more interface parameters 314 of the top surface 304T of the package 304 include one or more of: an impedance value, a distribution of impedance, an RC time, and a distribution of the RC time.

In some embodiments, a heat controlling module (e.g., the TIM 318 in FIG. 3) is disposed in proximity to, and separated by a gap from, the top surface 304T of the package 304. Gap characteristics of the gap are determined based on the one or more electrical signals 312 or interface parameters 314. Further, in some embodiments, the one or more electrical signals 312 are measured and the one or more interface parameters 314 are determined during an extended duration of time. A variation of the gap characteristics of the gap is monitored during the extended duration of time.

In some embodiments, a heat controlling module (e.g., the TIM 318 in FIG. 3) is disposed in proximity to, and separated by a gap from, the top surface 304T of the package 304. The electronic device 300 (FIG. 3) determines one or more of: a type, a material state, a material quality, a temperature, a coverage, a uniformity level, a damage condition, and a variation of a gap material that fills the gap. Further, in some embodiments, the gap between the package 304 and the heat controlling module (e.g., the TIM 318 in FIG. 3) is filled with air, a thermal interface material (e.g., the TIM 316 in FIG. 3), or a combination thereof, and the thermal interface material (e.g., the TIM 316 in FIG. 3) includes one or more of: a thermal paste, a thermal adhesive, a thermal gap filler, a thermally conductive pad, a phase-change material, a thermal tape, and a metal thermal interface material. Additionally, in some embodiments, based on the one or more interface parameters 314, it is determined that the gap material loses contact to the heat controlling module (e.g., the TIM 318 in FIG. 3).

In some embodiments, it is determined that the one or more interface parameters 314 do not satisfy a package criterion. An alert message is generated to report an associated package failure condition.

In some embodiments, the plurality of electrodes 310 include four electrodes 310 that are distributed at four substantially symmetric locations on the top surface 304T of the package 304, and the four electrodes 310 are coupled to form four nodes of a Wheatstone Bridge diamond shaped circuit 600 (FIGS. 6A and 6B). Further, in some embodiments, the electronic device checks on a balance voltage 604 of two arms of the Wheatstone Bridge diamond shaped circuit 600, and based on the balance voltage 604, determines that a portion of a gap that is formed above the top surface 304T of the package 304 has varied.

In some embodiments, the electronic module 300 further includes a solid state drive (SSD) that is enclosed in the package 304, which is mounted on the package substrate 302, and the electronic module 300 is applied in a data center computer system.

In some embodiments (FIG. 4), a first subset of the plurality of electrodes 310A are coupled to ground. The one or more interface parameters 314 of the top surface 304T of the package 304 include an impedance of each of a second subset of electrodes 310R with reference to the ground. Further, in some embodiments, for one of the second subset of electrodes 310R, a first drive voltage is applied on the respective electrode 310R, and a first drive current passing through the respective electrode 310R is measured. Alternatively, in some embodiments, for one of the second subset of electrodes 310R, a second drive current is delivered to the respective electrode 310R, and a second drive voltage applied on the respective electrode 310R is measured. In an example, the first subset of electrodes 310A only includes a single electrode 310A.

In some embodiments, each of a subset of electrodes 310 is coupled to an electrical path that runs through the package 304 and is coupled to an electrode 320 (FIG. 3) located on a bottom surface of the package 304, and the electrode 320 located on the bottom surface of the package 304 is electrically coupled to a respective one of the one or more connectors 308.

This method requires that electrodes 310 formed on a package 304 of an integrated circuit 315. These electrodes 310 are exposed and visible to naked eyes on a top surface 304T of the package 304, and can be easily identified by visual inspection. In some embodiments, a first voltage level is detected on one or more active electrodes 310 while no second voltage level is detected on one or more other electrodes 310, indicating that these other electrodes are yet to be electrically coupled via a conductive interface material. In some embodiments, an SSD changes operation after a TIM is removed from a package in a controlled thermal environment, indicating a change of thermal conductivity. In response to detection of a change of the SSD operation, a firmware of the SSD issues a flag indicating the change of thermal conductivity, and automatically implements throttling the SSD, limiting bandwidth, disabling circuit components.

The terminology used in the description of the various described implementations herein is for the purpose of describing particular implementations only and is not intended to be limiting. As used in the description of the various described implementations and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. A method for monitoring a package of an electronic device, the method comprising:
providing an electronic module including a package and a package substrate, wherein the package includes a plurality of electrodes that are exposed on a top surface of the package and electrically coupled to one or more connectors of the package substrate;
measuring one or more electrical signals via the one or more connectors of the package substrate; and
determining one or more interface parameters of the top surface of the package based on the one or more electrical signals.

2. The method of claim 1, measuring one or more electrical signals further comprising:
measuring one or more of: a voltage level, a current level, a rise time, a fall time, a delay time, a duty cycle, a high level time, and a low level time of a subset of the one or more electrical signals.

3. The method of claim 1, wherein the one or more interface parameters include an impedance that is associated with the plurality of electrodes exposed on the top surface of the package, the method further comprising one of:
in accordance with a determination that the impedance is greater than a first impedance threshold, determining that the top surface of the package is next to an air gap;
in accordance with a determination that the impedance is greater than a second impedance threshold, determining that the top surface of the package is next to a non-conductive thermal interface material;
in accordance with a determination that the impedance is less than a third impedance threshold, determining that the top surface of the package is next to an electrically conductive thermal interface material; and
in accordance with a determination that the impedance is between the second and third impedance thresholds, determining that the top surface of the package is next to the non-conductive thermal interface material and further to an electrically conductive thermal interface material;
wherein the first impedance threshold is greater than the second impedance threshold, which is greater than the third impedance threshold.

4. The method of claim 1, further comprising:
providing a heat controlling module that is disposed in proximity to, and separated by a gap from, the top surface of the package; and
determining gap characteristics of the gap.

5. The method of claim 4, wherein the one or more electrical signals are measured and the one or more interface parameters are determined during an extended duration of time, the method further comprising:
monitoring a variation of the gap characteristics of the gap during the extended duration of time.

6. The method of claim 1, further comprising:
providing a heat controlling module that is disposed in proximity to, and separated by a gap from, the top surface of the package; and
determining one or more of: a type, a material state, a material quality, a temperature, a coverage, a uniformity level, a damage condition, and a variation of a gap material that fills the gap.

7. The method of claim 6, wherein the gap between the package and the heat controlling module is filled with air, a thermal interface material, or a combination thereof, and the thermal interface material includes one or more of: a thermal paste, a thermal adhesive, a thermal gap filler, a thermally conductive pad, a phase-change material, a thermal tape, and a metal thermal interface material.

8. The method of claim 7, wherein based on the one or more interface parameters, it is determined that the gap material loses contact to the heat controlling module.

9. The method of claim 1, further comprising:
determining that the one or more interface parameters do not satisfy a package criterion; and
generating an alert message to report an associated package failure condition.

10. The method of claim 1, further comprising:
coupling a first subset of the plurality of electrodes to ground; and
wherein the one or more interface parameters of the top surface of the package includes an impedance of each of a second subset of electrodes with reference to the ground.

11. The method of claim 10, measuring the one or more electrical signals further comprising, for each of the second subset of electrodes, implementing one of:
(1) applying a first drive voltage on the respective electrode, and measuring a first drive current passing through the respective electrode; and
(2) delivering a second drive current to the respective electrode, and measuring a second drive voltage applied on the respective electrode.

12. An electronic device, comprising:
a package substrate including one or more connectors;
a package including a plurality of electrodes, wherein the plurality of electrodes are exposed on a top surface of the package and electrically coupled to the one or more connectors; and
an interface circuit coupled to the one or more connectors of the package substrate, wherein the interface circuit is configured to measure one or more electrical signals via one or more connectors of the package substrate and determine one or more interface parameters of the top surface of the package based on the one or more electrical signals.

13. The electronic device of claim 12, wherein the package is physically coupled to the package substrate and configured to enclose and protect an integrated circuit.

14. The electronic device of claim 13, wherein:
the electronic device further includes the integrated circuit, and the integrated circuit further includes an interface circuit; and
the interface circuit is electrically coupled to the one or more connectors of the package substrate via one or more conductor traces of the package substrate, and configured to measure the one or more electrical signals and determine the one or more interface parameters.

15. The electronic device of claim 12, wherein:
the package substrate includes a main printed circuit board;
an interface circuit is configured to measure the one or more electrical signals and determine the one or more interface parameters; and
the interface circuit is mounted on the main printed circuit board and electrically coupled to the one or more connectors of the package substrate via one or more conductor traces of the main printed circuit board.

16. The electronic device of claim 12, wherein the plurality of electrodes is distributed on the top surface of the package, and the one or more interface parameters of the top surface of the package include one or more of: an impedance value, a distribution of impedance, an RC time, and a distribution of the RC time.

17. The electronic device of claim 12, wherein the plurality of electrodes include four electrodes that are distributed at four substantially symmetric locations on the top surface of the package, and the four electrodes are coupled to form four nodes of a Wheatstone Bridge diamond shaped circuit.

18. The electronic device of claim 17, determining the one or more interface parameters further comprising:
checking on a balance voltage of two arms of the Wheatstone Bridge diamond shaped circuit; and
based on the balance voltage, determining that a portion of a gap that is formed above the top surface of the package has varied.

19. The electronic device of claim 12, wherein the electronic device further includes a solid state drive (SSD) that is enclosed in the package, which is mounted on the package substrate, and the electronic device is applied in a data center computer system.

20. The electronic device of claim 12, wherein each of a subset of electrodes is coupled to an electrical path that runs through the package and is coupled to an electrode located on a bottom surface of the package, and the electrode located on the bottom surface of the package is electrically coupled to a respective one of the one or more connectors.
